(19) United States
(12) Patent Application Publication
(10) Pub. No.: US 2026/0036377 A1
(43) Pub. Date: Feb. 5, 2026

(54) COOLER AND COOLING DEVICE

(71) Applicant: KYUSHU UNIVERSITY, NATIONAL UNIVERSITY CORPORATION, Fukuoka-shi, Fukuoka (JP)

(72) Inventors: Shoji MORI, Fukuoka-shi (JP); Tsutomu HISANO, Fukuoka-shi (JP); Yasuyuki TAKATA, Fukuoka-shi (JP)

(73) Assignee: KYUSHU UNIVERSITY, NATIONAL UNIVERSITY CORPORATION, Fukuoka-shi, Fukuoka (JP)

(21) Appl. No.: 18/843,037

(22) PCT Filed: Feb. 22, 2023
(86) PCT No.: PCT/JP2023/006573

§ 371 Date: Apr. 7, 2025

(30) Foreign Application Priority Data
Mar. 1, 2022 (JP) 2022-031229

(51) Int. Cl. F28D 15/02; H05K 7/20

(52) U.S. Cl. CPC F28D 15/0266; H05K 7/20336

(57) ABSTRACT

Provided is a cooler and a cooling device capable of inducing boiling at a low degree of superheat by suppressing an increase in the Onset of Nucleate Boiling. A cooler of a boiling method type for cooling a heat generating body, comprising: a container for storing a working fluid; a cooling member made of a porous body and disposed in the container so as to face a surface of the heat generating body; and at least one thin metal wire or thin metal film disposed between the surface of the heat generating body and the cooling member and configured to be heatable.

### FIELD OF THE INVENTION

The present invention relates to a cooler and a cooling device.

### BACKGROUND OF THE INVENTION

A cooler of a boiling method type is known, in which a heat generating body is cooled from the outside with a working fluid such as water. The boiling methods include a pool boiling method and a forced convection boiling method. The cooling mechanism of a heat generating body of the pool boiling method type will be described. A conventional cooler of the pool boiling method type generally includes a container and a working fluid contained in the container, and the container has a contact part with the heat generating body to be cooled. When heat is generated in the heat generating body and the heat is transferred to the working fluid through the contact part, the working fluid present in the vicinity of the contact part boils. When vapor is generated by boiling, the working fluid is supplied to the contact part due to the density difference between the gas and liquid. The newly supplied working fluid further evaporates and removes heat from the heat generating body. A cooler of the pool boiling method type does not require an external power source for circulating the liquid as in the forced convection boiling method, and is therefore advantageous in terms of compactness and energy saving.

However, when a large heat flux is applied to the contact part, the amount of evaporation of the working fluid increases, and the contact part begins to be covered with vapor. When the contact part is completely covered with vapor and becomes dry, and the working fluid is no longer supplied to the contact part, the cooling capacity of the cooler is significantly deteriorated. The heat flux in this state is called the “critical heat flux (CHF)”.

To address these problems, Patent Literature 1 discloses a structure in which a porous body of a predetermined shape is placed between the heat generating body and the water in a cooling container, and water is supplied to the heat generating body by the capillary action of the porous body while the vapor generated thereby is discharged into the water in the container, thereby dramatically improving the conventional critical heat flux with a simple structure.

### CITATION LIST

### Patent Literature

[Patent Literature 1] Japanese Patent Application Publication No. 2009-139005 A

### SUMMARY OF THE INVENTION

However, even if the cooler has a structure in which a porous body is provided between the heat generating body and the working fluid in the cooling container, if there are no boiling nuclei near the surface of the heat generating body, boiling does not occur smoothly, and as shown by the boiling curve in FIG. 1, the temperature at which boiling begins to occur on the surface of the heat generating body, that is, the Onset of Nucleate Boiling (ONB) rises dramatically. In such a case, the degree of superheat (ΔTsat) increases, and problems such as damage and failure occur depending on the type of heat generating body. In coolers of the conventional boiling method type, research and development on improving the above-mentioned CHF has been actively conducted, but there are few reports on technologies for lowering the ONB.

In order to solve such problems, an object of the present invention is to provide a cooler and a cooling device that are capable of inducing boiling at a low degree of superheat by suppressing an increase in the Onset of Nucleate Boiling.

After extensive research, the inventors have discovered that by providing at least one heatable thin metal wire or thin metal film between the surface of the heat generating body and a cooling member made of a porous body, the heated thin metal wire or thin metal film can seed boiling nuclei, thereby making it possible to induce boiling at a low degree of superheat.

The above problems are solved by the present invention, which is specified as follows.

(1) A cooler of a boiling method type for cooling a heat generating body, comprising:
a container for storing a working fluid;
a cooling member made of a porous body and disposed in the container so as to face a surface of the heat generating body; and
at least one thin metal wire or thin metal film disposed between the surface of the heat generating body and the cooling member and configured to be heatable.

(2) The cooler according to (1), wherein the thin metal wire or thin metal film is configured to be heatable by a passage of electric current.

(3) The cooler according to claim 1) or (2), wherein a plurality of thin metal wires or thin metal films are provided.

(4) The cooler according to any one of (1) to (3), wherein the porous body comprises a working fluid supply section that supplies the working fluid to the surface of the heat generating body by capillary action, and a vapor exhaust section that exhausts vapor generated on the surface of the heat generating body to the working fluid side.

(5) The cooler according to (4), wherein the porous body has a honeycomb structure.

(6) The cooler according to any one of (1) to (5), further comprising a working fluid introduction body that is laminated on the working fluid side of the porous body and introduces the working fluid into the porous body.

(7) A cooling device comprising:
the cooler according to any one of (1) to (6); and
a condenser that is connected to the container of the cooler and liquefies evaporated working fluid.

According to the present invention, it is possible to provide a cooler and a cooling device capable of inducing boiling at a low degree of superheat by suppressing an increase in the Onset of Nucleate Boiling.

### BRIEF DESCRIPTION OF THE DRAWINGS

FIG. 1 is a graph showing boiling curve of conventional cooler;

FIG. 2 is a schematic diagram of cooler 10 of a boiling method type according to an embodiment of the present invention;

FIG. 3 is an enlarged schematic cross-sectional view of a heat generating body 13, a thin metal wire 15, and a cooling member 14;

FIG. 4 is a schematic plan view showing the positional relationship between the thin metal wire 15 and the cooling member 14;

FIG. 5 is a schematic diagram of cooler 10 of a boiling method type according to another embodiment of the present invention;

FIG. 6 is a plan view of a porous body having a honeycomb structure;

FIG. 7 is a schematic diagram of cooler 10 of a boiling method type according to another embodiment of the present invention;

FIG. 8 is a schematic diagram of a cooling device 20 including a cooler 10 according to an embodiment of the present invention;

FIG. 9 is a schematic diagram of the pool boiling experimental apparatus used in the test example;

FIG. 10 is a schematic diagram showing the design of the ITO film (heat generating body) according to the test example;

FIG. 11 is a schematic diagram showing the arrangement of stainless steel thin wires according to the test example;

FIG. 12 is a photograph of the appearance of NA honeycomb of the honeycomb porous body;

FIG. 13 is a graph showing boiling curves according to test examples; and

FIG. 14 is a schematic plan view showing the positional relationship between a thin metal film 22 and a cooling member 14.

### DETAILED DESCRIPTION OF THE INVENTION

Next, the embodiments of the present invention will be described in detail with reference to the drawings. It should be understood that the present invention is not limited to the following embodiments, and that appropriate changes and improvements in the design may be made based on the ordinary knowledge of those skilled in the art without departing from the spirit of the present invention.

### <Cooler>

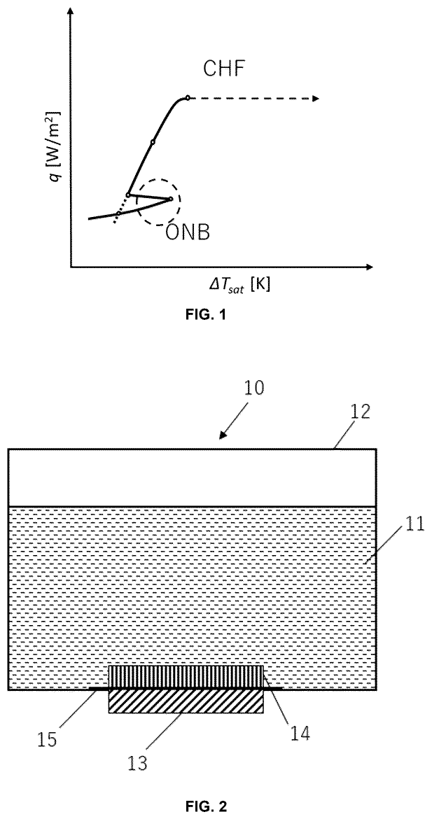

FIG. 2 is a schematic diagram of cooler 10 of a boiling method type according to an embodiment of the present invention. The cooler 10 includes a container 12 that contains a working fluid 11, and a cooling member 14 that is provided in the container 12 so as to be in contact with the working fluid 11 and to face a surface of a heat generating body 13.

The cooling member 14 is made of a porous body. By making the cooling member 14 of a porous body, the working fluid 11 can be supplied to the surface of the heat generating body 13 by capillary action. In addition, the pores of the porous body can become the nuclei of boiling near the surface of the heat generating body 13. The porous body can be formed of, for example, ceramics such as cordierite, sintered metal, or electrolytically deposited metal. In particular, it is desirable to make the porous body of a porous body having good wettability such as an oxide, or a porous body that has been processed to improve wettability such as by plasma irradiation. In addition, the form of the porous body is not particularly limited, and for example, the porous body may be made of an aggregate of porous particles. In addition, the porous body may be made of a porous layer.

As the working fluid 11, for example, liquids having surface tension such as water, low-temperature fluids, refrigerants, organic solvents, etc. In order to cope with the increase in heat generation density of heat generating bodies such as electronic elements in recent years, in addition to general electrical insulating fluids such as fluorocarbon (FC), freon (CFC), alternative freon (HCFC or HFC, etc.), pure water, and ultrapure water, electrical insulating fluids with very high wettability such as HFE7100 (manufactured by 3M Japan Ltd.) can also be suitably used.

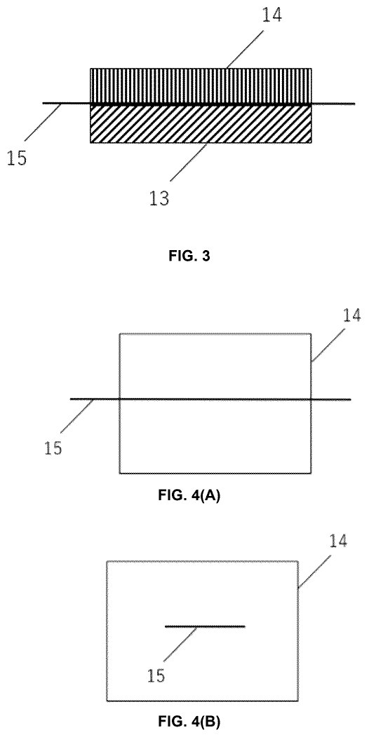

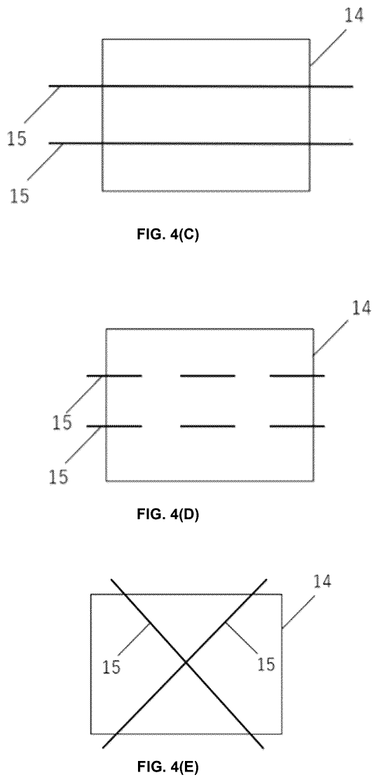

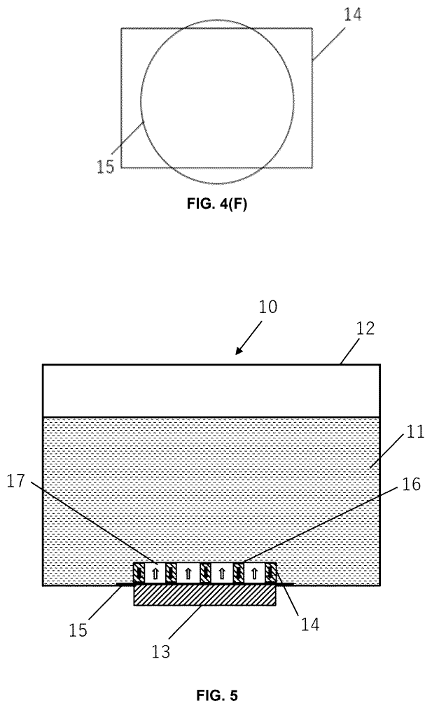

The cooler 10 further includes at least one thin metal wire 15 that is provided between the surface of the heat generating body 13 and the cooling member 14 and is configured to be heatable. FIG. 3 shows an enlarged schematic cross-sectional view of the heat generating body 13, the thin metal wire 15, and the cooling member 14. FIG. 4(A) shows a schematic diagram showing the positional relationship between the thin metal wire 15 and the cooling member 14 when the configuration in FIG. 3 is viewed in plan. In the embodiment shown in FIG. 3 and 4(A), one thin metal wire 15 is provided between the heat generating body 13 and the cooling member 14 and passes through the center of the heat generating body 13 and the cooling member 14 in plan view.

As described above, when the cooling member 14 provided to face the heat generating body 13 is made of a porous body, the pores of the porous body can become the nuclei of boiling near the surface of the heat generating body 13. However, if the nuclei of boiling are not generated for some reason, boiling does not occur smoothly, and the Onset of Nucleate Boiling (ONB) rises dramatically. For example, in recent years, data centers, which are expected to see a significant increase in demand, consume a large amount of energy, so the impact of saving energy is extremely large, but the heat generation density has also increased significantly, and such a large increase in ONB is a concern. In particular, when cooling electronic elements with cooler of a boiling method type, an electrically insulating fluid is sometimes used as the working fluid, but if a highly wettable electrically insulating fluid such as HFE7100 (manufactured by 3M Japan Co., Ltd.) is used, even the pores of the porous body that become the nuclei of boiling are wetted. In such a case, there is no nucleus of boiling near the surface of the heat generating body 13, boiling does not occur smoothly, and the ONB rises dramatically. It is known that the upper operating temperature limit to ensure safe operation of electronic elements is, for example, 85 to 105° C. for CPUs or FPGAS, approximately 150° C. for Si power devices, and 300 to 400° C. for SiC power devices. However, if the ONB rises in this manner, the upper operating temperature limit will be exceeded immediately after startup, causing problems such as damage or failure of the electronic elements.

To address such problems, the cooler 10 according to the embodiment of the present invention includes thin metal wire 15 that is provided between the surface of the heat generating body 13 and the cooling member 14 and is configured to be heatable, so that the heated thin metal wire 15 generates vapor, which can seed boiling nuclei (gas bubbles) in the pores of the porous body near the surface of the heat generating body 13. The presence of boiling nuclei near the surface of the heat generating body 13 allows boiling to occur smoothly. As a result, boiling can be caused at a low degree of superheat, and an increase in ONB can be suppressed.

The thin metal wire 15 may be heated by electrically connecting an arbitrary position to an external power source and passing an electric current through the wire. In this manner, the thin metal wire 15 may be configured to be heatable by passing an electric current through the wire. The heating temperature of the thin metal wire 15 is not particularly limited as long as it is equal to or higher than the boiling point of the working fluid 11. The amount of electric current passing through the thin metal wire 15 can be appropriately adjusted so as to boil the working fluid 11, and it is preferable in terms of cost to use a pulsed electric current to extremely reduce the electric power required for heating. Alternatively, the thin metal wire 15 may be configured to be heatable by electromagnetic induction or the like.

The thin metal wire 15 is not particularly limited in terms of the material as long as they are thin metal wires that can be heated, but materials with high electrical resistivity, such as stainless steel wires, platinum wires, nichrome wires, Kanthal wires, or molybdenum wires, are preferred because they can be heated by voltage, do not require a large current for heating, and enable miniaturization of the cooler 10. The electrical resistivity of the thin metal wire 15 is preferably 2 to 120μΩ · cm.

The size of the thin metal wire 15 is not particularly limited. For example, even if the size of the thin metal wire 15 is very small and the amount of bubbles generated by heating is very small, it provides a boiling nucleus near the surface of the heat generating body 13, and boiling spreads from the boiling nucleus along the surface direction of the heat generating body 13, so that boiling occurs smoothly. If the size of the thin metal wire 15 is very large, problems arise in terms of cost and ease of handling, but the object of the present invention of generating boiling at a low degree of superheat and suppressing the rise of ONB can be achieved.

The thinner the thin metal wire 15 (the smaller the diameter), the less power is required to heat it and generate bubbles. If the thin metal wire 15 is thin enough to be within the range of the surface roughness of the porous body, the porous body will come into contact with the surface of the heat generating body, and this has the effect of accelerating the activation of cavities (fine scratches on the surface of the heat generating body). From this perspective, the diameter of the thin metal wire 15 is preferably 100 μm or less, and more preferably 50 μm or less. The diameter of the thin metal wire 15 used in the embodiment of the present invention is typically 10 to 50 μm.

The shorter the length of the thin metal wire 15, the less power is required to heat it and generate bubbles. From this perspective, the length of the thin metal wire 15 is preferably 100 mm or less, and more preferably 50 mm or less. The length of the thin metal wire 15 used in the embodiment of the present invention is typically 20 to 50 mm.

The thin metal wire 15 may be provided in a single or multiple manner. FIG. 4(A) shows an example in which a single thin metal wire 15 is provided so as to pass through the center of the heat generating body 13 and the cooling member 14 in a plan view and to protrude from the heat generating body 13 and the cooling member 14, but this is not limited to this. For example, as shown in FIG. 4(B), a single thin metal wire 15 may be provided so as to pass through the center of the heat generating body 13 and the cooling member 14 in a plan view and not to protrude from the heat generating body 13 and the cooling member 14. As shown in FIG. 4(C), two thin metal wires 15 may be provided so as to extend parallel to each other across the center of the heat generating body 13 and the cooling member 14 in a plan view. As shown in FIG. 4(D), six thin metal wires 15 may be provided at a predetermined interval. As shown in FIG. 4(E), two thin metal wires 15 may be provided so as to cross each other. The number of thin metal wires 15 is not limited to one or two, but may be three or more. The thin metal wires 15 may be formed by connecting a plurality of wires made of nonmetallic material such as resin. When a plurality of thin metal wires 15 are provided, it is preferable to configure the thin metal wires 15 so as to be heatable by electrically connecting all of the thin metal wires 15 to an external power source by wiring or the like.

Even if there is only one thin metal wire 15, it will generate bubbles when heated, providing a boiling nucleus near the surface of the heat generating body 13, and boiling will spread from the boiling nucleus along the surface direction of the heat generating body 13, so that boiling will occur smoothly. Therefore, from the viewpoint of suppressing the amount of power required to energize the thin metal wire 15, it is preferable to use a single thin metal wire 15. On the other hand, if multiple thin metal wires 15 are provided, boiling nuclei (air bubbles) can be more reliably seeded in the pores of the porous body near the surface of the heat generating body 13. This has the advantage that the air bubbles generated by the thin metal wire 15 are not wasted and the targeted pores of the porous body can be reliably seeded.

Also, as shown in FIG. 4(F), a single thin metal wire 15 may be provided in a circular shape. When viewed from above, the thin metal wire 15 is not limited to a circular shape as shown in FIG. 4(F), but may be formed in a triangular shape, a rectangular shape, or other polygonal shape. It may also be formed in a shape with knots such as a ribbon shape.

Also, a thin metal film 22 may be provided instead of the thin metal wire 15. That is, the thin metal film 22 is provided between the surface of the heat generating body 13 and the cooling member 14, and configured to be heatable. With this configuration, the heated thin metal film 22 generates vapor, which can seed boiling nuclei (air bubbles) in the pores of the porous body near the surface of the heat generating body 13. If there are boiling nuclei near the surface of the heat generating body 13, boiling occurs smoothly. As a result, boiling can be caused at a low degree of superheat, and the rise in ONB can be suppressed.

The thin metal film 22 may be heated by electrically connecting an arbitrary position to an external power source with wiring or the like and passing an electric current through the thin metal film 22. In this way, the thin metal film 22 may be configured to be heated by passing an electric current. The heating temperature of the thin metal film 22 is not particularly limited as long as it is equal to or higher than the boiling point of the working fluid 11. In addition, the amount of electric current passing through the thin metal film 22 can be appropriately adjusted so as to boil the thin metal film 22, but by making the electric current a pulse current in particular, the required power for heating can be made extremely small, which is preferable in terms of cost. In addition, the thin metal film 22 may be configured to be heated by electromagnetic induction or the like.

The thin metal film 22 is not particularly limited in terms of the material of which it is made, so long as it is made of a metal that can be heated. However, for example, materials with high electrical resistivity, such as stainless steel wire, platinum wire, nichrome wire, Kanthal wire, or molybdenum wire, are preferred because they can be heated by voltage, do not require a large current for heating, and allow the cooler 10 to be made smaller. The electrical resistivity of the thin metal film 22 is preferably 2 to 120μΩ·cm.

The thin metal film 22 may be triangular, rectangular, other polygonal, circular, elliptical, or indefinite in plan view. The smaller the thin metal film 22, the less power is required to heat it and generate bubbles. From this perspective, it is preferred that the thin metal film 22 has an area of 0.01 to 1 cm² and a thickness of 1 to 50 μm in plan view. The thin metal film 22 used in the embodiment of the present invention typically has an area of 0.01 to 0.1 cm² and a thickness of 10 to 20 μm in plan view.

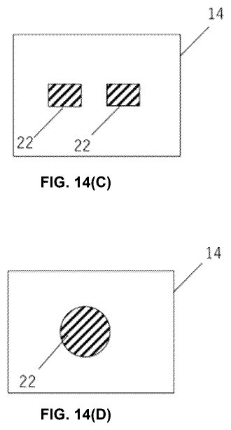

The thin metal film 22 may be provided in multiple bodies, not just one body. FIG. 14(A) shows an example in which one rectangular thin metal film 22 is provided so as to pass through the center of the heat generating body 13 and the cooling member 14 in a plan view and to protrude from the heat generating body 13 and the cooling member 14, but this is not limited to the above. For example, as shown in FIG. 14(B), one rectangular thin metal film 22 may be provided in the center of the heat generating body 13 and the cooling member 14 in a plan view so as not to protrude from the heat generating body 13 and the cooling member 14. Also, as shown in FIG. 14(C), two thin metal film 22 may be provided in parallel, sandwiching the center of the heat generating body 13 and the cooling member 14 in a plan view. Also, as shown in FIG. 14(D), one circular thin metal film 22 may be provided in the center of the heat generating body 13 and the cooling member 14 in a plan view. The thin metal film 22 is not limited to one or two bodies, but may be three or more bodies. Also, the thin metal film 22 may be formed by connecting multiple bodies with thin nonmetallic wires such as resin. In addition, when a plurality of thin metal film 22 are provided, it is preferable to configure all of the thin metal film 22 to be heatable by electrically connecting them to an external power source with wiring or the like.

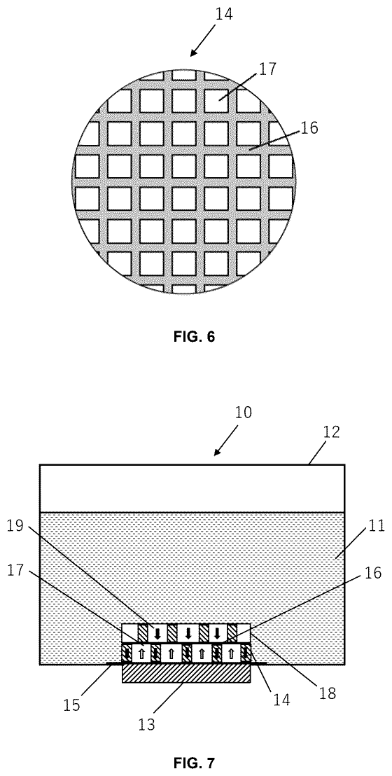

As shown in the schematic diagram of FIG. 5, the porous body of the cooling member 14 is preferably equipped with a working fluid supply section 16 that supplies the working fluid 11 to the surface of the heat generating body 13 by capillary action, and a vapor exhaust section 17 that exhausts the vapor generated on the surface of the heat generating body 13 to the working fluid side. As shown in the plan view of FIG. 6, an example of a porous body of the cooling member 14 equipped with such a working fluid supply section 16 and vapor exhaust section 17 is a porous body having a honeycomb structure.

The working fluid supply section 16 supplies the working fluid 11 to the surface of the heat generating body 13 by capillary action. The vapor exhaust section 17 exhausts the vapor generated by the heat from the heat generating body 13 from the surface of the heat generating body 13 to the working fluid side. In this embodiment, the lattice-like porous layer portion around the rectangular holes of the honeycomb structure of the porous body functions as a working fluid supply section 16 that supplies the working fluid 11 to the surface of the heat generating body 13 by capillary action, and the rectangular holes function as vapor exhaust section 17 that exhausts the vapor generated on the surface of the heat generating body 13 to the working fluid side. By supplying the working fluid 11 and discharging the vapor using separate paths in this way, it is possible to prevent the vapor from covering the contact part and limiting the critical heat flux. As a result, the critical heat flux of the cooler 10 is improved.

The pore radius of the porous body may be the radius of the pores that each porous body originally has, or may be the radius of the pores formed in each porous body. Here, the shape of the pores of the porous body can be various shapes such as polygonal, circular, elliptical, etc., and the “pore radius” refers to the radius of the circumscribed circle in such various pore shapes.

As for the shape of the porous body, since the contact area of the porous body with the contact part is large, the size of the holes for releasing the vapor generated at the contact part into the water is preferably small, for example, the hole radius can be 100 to 2000 μm. In addition, since the pressure loss when passing through the porous bottom can be reduced, the distance between the holes for releasing the vapor generated at the contact part into the water is preferably small, for example, 100 to 1000 μm.

In FIG. 5, the working fluid supply section 16 and the vapor exhaust section 17 are illustrated as being perpendicular to the surface of the lower heat generating body 13 and the working fluid side above, but the working fluid supply section 16 and the vapor exhaust section 17 may be configured to be curved or bent, for example, as long as they provide a path between the surface facing the surface of the heat generating body 13 and the surface on the working fluid side, respectively.

The cooling member 14 may have a structure in which a first porous body facing the surface of the heat generating body 13 and a second porous body on the working fluid side are laminated. In this case, the second porous body has a working fluid supply section that supplies the working fluid 11 to the first porous body, and a vapor exhaust section that exhausts the vapor discharged from the first porous body to the working fluid side. The cooling member 14 may also have a third porous body on the working fluid side of the second porous body, making it three layers in total. In this case, the third porous body has a working fluid supply section that supplies the working fluid 11 to the second porous body, and a vapor exhaust section that exhausts the vapor discharged from the second porous body to the working fluid side. Similarly, the porous body may have a structure of four or more layers in total, with multiple porous bodies laminated on the working fluid side of the second porous body. In this way, when the porous body of the cooling member 14 has a structure consisting of multiple laminated layers, the amount of working fluid 11 supplied to the surface of the heat generating body 13 and the amount of vapor discharged from the heat generating body 13 are both abundant, and the limiting heat flux can be more effectively prevented from being limited.

As shown in the schematic diagram of FIG. 7, the cooler 10 is preferably further provided with a working fluid introduction body 18, which is provided so as to be laminated on the working fluid side of the porous body of the cooling member 14 and has a working fluid introduction section 19 that introduces the working fluid 11 to the porous body. From the viewpoint of the capillary limit mechanism, the thickness of the porous body of the cooling member 14 is preferably thin, but if it is thinner than the thickness of the macro liquid film, there is a problem that liquid drying up is likely to occur inside the porous body and the critical heat flux becomes small. In response to this, as shown in FIG. 7, by providing a working fluid introduction body 18 that introduces the working fluid 11 to the porous body, on the porous body (on the working fluid side), there is a working fluid introduction body 18 that supplies the working fluid 11 abundantly to the porous body and holds the working fluid 11 above the porous body between the porous body and the vapor mass above it. Therefore, even if the thickness of the porous body is made thin, the occurrence of liquid drying up is suppressed and the critical heat flux can be prevented from becoming small. In addition, since the amount of liquid supplied by the working fluid introduction body 18 is preferably large, it is preferable to make the thickness of the working fluid introduction body 18 large. Specifically, for example, when the thickness of the porous body is thinned to about 100 μm, the thickness of the working fluid introduction body 18 is preferably about 1 mm or more.

The working fluid introduction body 18 may have a plurality of holes penetrating in the height direction, and the plurality of holes may constitute the working fluid introduction section 19. In addition, the plurality of holes constituting the working fluid introduction section 19 may have a circular or polygonal cross section.

The material constituting the working fluid introduction body 18 may be a porous material or a non-porous material. The material constituting the working fluid introduction body 18 may be formed using metals such as stainless steel and Teflon (registered trademark), resins, etc. In particular, by forming the working fluid introduction body 18 from a metal, the wettability of the working fluid introduction body 18 is improved and the hydrophilicity is improved, so that it is possible to take in a larger amount of the working fluid 11 and supply it to the surface of the heat generating body 13.

In another embodiment of the present invention, the entire heat generating body 13 can be immersed in the working fluid 11, or a part of the heat generating body 13 can be immersed below the liquid surface of the working fluid 11 to perform cooling. In this case, the heat generating body 13 can take various forms depending on the case, such as floating or placed on the bottom surface of the container 12, but the point is that by attaching a cooling member 14 made of a porous body to the part immersed in the working fluid 11, cooling can be performed in the same manner as in the above example.

### <Cooling Device>

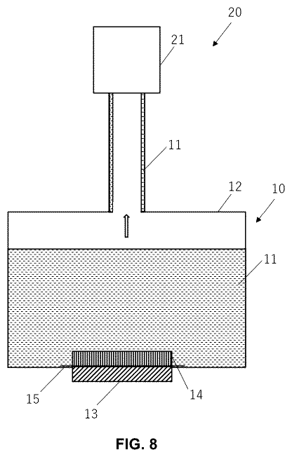

FIG. 8 shows a schematic diagram of a cooling device 20 equipped with a cooler 10 according to an embodiment of the present invention. The cooling device 20 includes the cooler 10 and a condenser 21 connected to the container 12. In the condenser 21, the evaporated working fluid 11 is liquefied and returned to the container 12. The cooling device 20 does not require an external power source such as a pump, and is excellent in compactness and energy saving as a whole device.

### <Applications>

The cooler 10 and cooling device 20 of the present invention can be applied to various electronic devices and other thermal devices with high heat generation density. For example, they can be used to improve the performance of capillary pump loops, semiconductor lasers, cooling of servers in data centers, freon-cooled chopper control devices, power electronic devices, etc. Alternatively, they can be used as water-cooled jackets installed on the sides or bottom of fireproof walls of large waste incinerators and the like to cool the walls from the outside and reduce damage.

### EXAMPLES

The present invention will be described in more detail below with reference to examples, but the present invention is not limited to these.

### Test Example 1

### Experimental Equipment

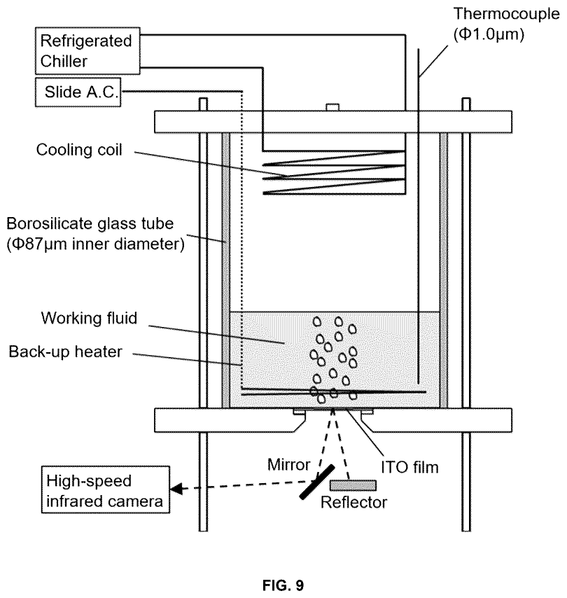

A pool boiling experimental equipment with the configuration shown in FIG. 9 was prepared as the experimental equipment. The pool boiling experimental equipment shown in FIG. 9 used a borosilicate glass tube as the cooler container, an electrically insulating fluid HFE7100 (manufactured by 3M Japan Ltd.) as the working fluid, and a rectangular ITO (Indium Tin Oxide) film as the heat generating body. The ITO film (heat generating body) was located at the bottom of the cooler container and was installed so that the working fluid in the container was in contact with its surface.

More specifically, first, a silicone sheet and an ITO film were placed on a Teflon (registered trademark) flange, and the ITO film was sealed by pressing down from above. A circuit was also assembled by soldering a conductor to the electrodes of the ITO film described in the design of the ITO film (heat generating body) described later, and heating was performed using a Stabitron type DC power supply (SCIZ-2B15 manufactured by Nippon Stabilizer Industry Co., Ltd.). For the experimental subject (3) described below, a stainless steel wire was placed on the ITO film and heated intermittently using a DC power source (ZX-S-800LAN, manufactured by Takasago Seisakusho). A borosilicate glass tube with an inner diameter of 87 mm was fixed with flanges on both ends to form a pool container. The working fluid was kept at saturation temperature by a back-up heater, and the temperature was measured using a thermocouple with a temperature calibration. The liquid height of the working fluid was 100 mm, and a condenser was attached to the top of the pool container to prevent the amount of liquid in the pool from changing due to boiling. The temperature of the bottom of the ITO film was measured with an infrared camera (A6700sc, manufactured by FLIR) through a mirror (gold mirror: S03-25-1/10, manufactured by Suruga Seiki). Copper coated with black body spray (ε=0.94) was used as the reflector.

### Design of ITO Film (Heat Generating Body)

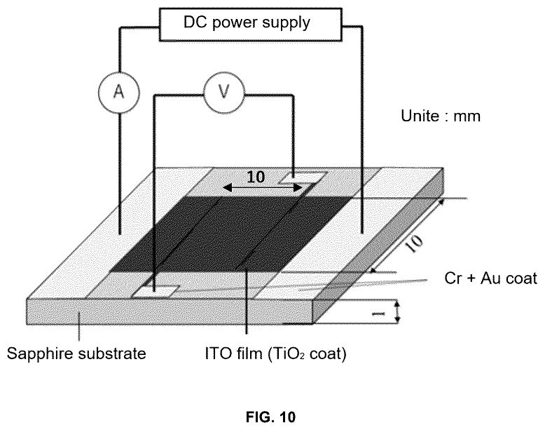

Details of the design of the ITO film are shown in FIG. 10. Cr (30 nm) and Au (200 nm) are deposited on both ends of a sapphire substrate (length×width=40 mm×40 mm, thickness 1 mm) as electrodes, and indium-tin oxide: ITO film (250 nm) and TiO₂ (100 nm) are deposited on the central area (20 mm×10 mm) as a heat generating body. The ITO film is a resistance when heated by electricity, and TiO₂ is deposited on top of the ITO film to improve wettability. The ITO film is a conductive film that is transparent to visible light and opaque to infrared rays with wavelengths of 3 to 5 μm. Sapphire is also transparent to both visible light and infrared rays with wavelengths of 3 to 5 μm. Therefore, by utilizing the fact that the ITO film is opaque to infrared rays with wavelengths of 3 to 5 μm and sapphire is transparent, the temperature at the bottom of the ITO film can be measured.

### Stainless Steel Thin Wire

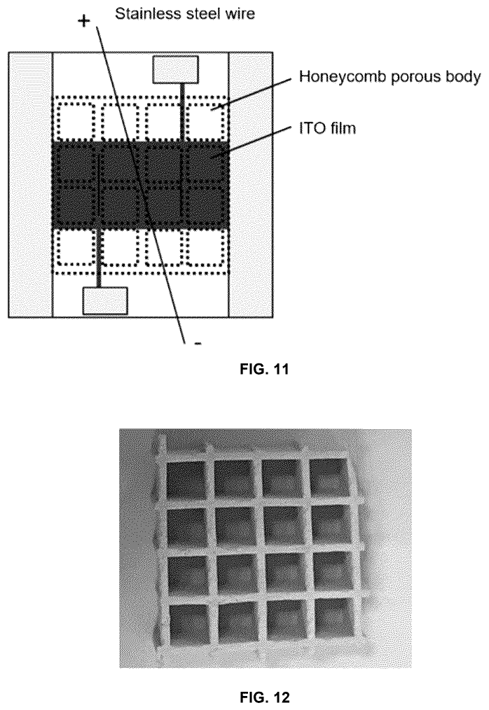

Details of the installation of the stainless steel thin wire are shown in FIG. 11. A thin stainless steel wire (diameter 50 μm, length 4 cm) was placed between the surface of the heat generating body and the honeycomb porous body, without contacting the electrodes. During the experiment, a direct current power supply of 37 W was used to heat intermittently so as not to cause thermal damage to the surface of the heat generating body.

### Honeycomb Porous Body

The honeycomb porous body used in (2) and (3) described below was the NA honeycomb (NA-180CR), a commercially available honeycomb porous body used for automobile exhaust gas treatment, shown in FIG. 12. The NA honeycomb had a rectangular outer shape of 20 mm×20 mm, a cell width of 5.0 mm, and a wall thickness of 1.0 mm. The components of the NA honeycomb were calcium aluminate (CaO·Al₂O₃): 30-50 mass %, fused silica (fused SiO₂): 40-60 mass %, and titanium dioxide (TiO₂): 5-20 mass %, and the effective thermal conductivity was 4 W/(m·K). In addition, the logarithmic differential pore volume distribution of the NA honeycomb showed a median pore radius of 0.129 μm, an average pore radius of 0.0372 μm, and a porosity of 24.8%. From the logarithmic differential pore volume distribution, it was found that the pores of the honeycomb porous body used in this experiment were relatively uniform, and that the median pore radius was also on the submicron order, making it a very dense porous body. The honeycomb porous body was fixed on the surface of the heat generating body by pulling it vertically downward with an even force with two 0.3 mm diameter stainless steel wires against the surface of the heat generating body.

### Experiment

Three types of experimental subjects were prepared: (1) a bare surface (nothing on the ITO film), (2) only a honeycomb porous body, and (3) a stainless steel wire sandwiched between the honeycomb porous body and the ITO film.

For each of the experimental devices (1) to (3), the working fluid was boiled for 1 hour using a back-up heater and degassed. Next, the ITO film was heated by applying electricity from a DC power source at atmospheric pressure and saturation temperature to generate heat.

In order to confirm durability, after the above boiling experiment, (1) was left at room temperature for 0, 1, and 4 hours, (2) was left at room temperature for 9, 20, and 24 hours, and (3) was left at room temperature for 6, 9, 24, and 46 hours, and then each was heated again and a boiling experiment was performed. Therefore, as the temperature is returned to normal, the pores on the surface of the heat generating body and within the honeycomb porous body gradually become wet, and when reheated, boiling is less likely to occur and the body is more likely to become overheated.

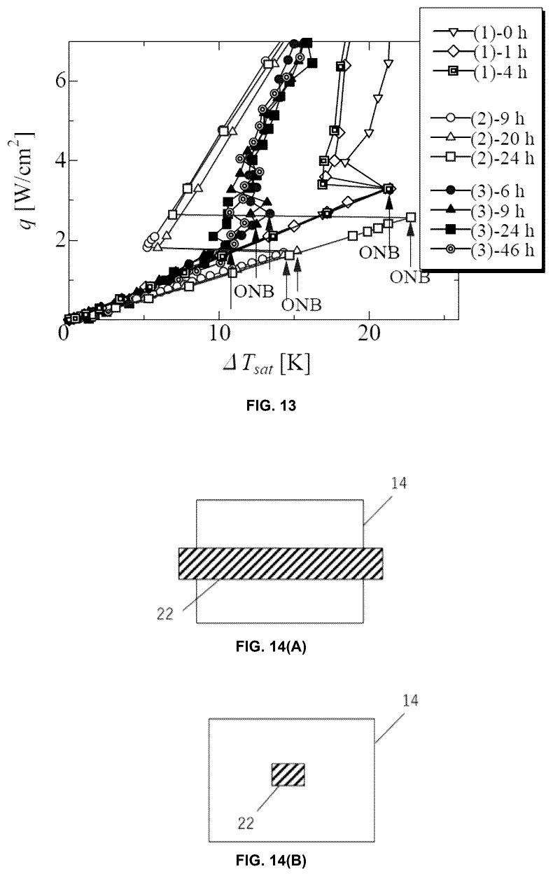

The boiling curves obtained from these experiments for the experimental subjects (1) to (3) are shown in FIG. 13.

According to FIG. 13, for the ONB, in the case of the bare surface (1), the superheat (ΔTsat) was approximately 21K. In the case of the honeycomb porous body only (2), where only the honeycomb porous body was provided, the superheat dropped to approximately 14K in 9 hours after the honeycomb porous body was immersed in the working fluid, but after 24 hours it rose to 23K, almost the same as the case of the bare surface. This is because the pores in the honeycomb porous body acted as bubble nuclei immediately after immersion, promoting foaming, but as time passed, the highly wettable working fluid filled the pores and the bubble nuclei disappeared.

When (3) a stainless steel wire was placed between the honeycomb porous body and the ITO film and heated, the degree of superheat dropped to about 13K after 6 hours, and boiling could be initiated at a stable low degree of superheat of about 12K even after 46 hours.

From the above, since the allowable temperature of the electronic element is ΔTsat=24.3K (about 80° C.), the surface temperature of the heat generating body rose to a temperature where the electronic element would be damaged if only the bare surface and the honeycomb porous body were placed, but it was found that the degree of superheat can be steadily reduced regardless of the passage of time by using a honeycomb porous body and a heated metal wire. This is thought to be due to the effect of the honeycomb porous body described above, as well as the fact that the heated metal wire was heated by electrical current to cause bumping on the metal wire, which caused the generated bubbles to seed the existing pores of the honeycomb porous body with bubble nuclei, promoting foaming. Note that the above test example was conducted using the working fluid (HFE7100) that most easily wets the pores of the honeycomb porous body, and it is believed that the method will be effective for all other working fluids as well.

In addition, in this embodiment, thin metal wires were used for heating in order to seed the pores of the porous body near the surface of the heat generating body with boiling nuclei (air bubbles), but it is believed that the same effect can be obtained by heating using a thin metal film instead, since air bubbles are generated by heating.

### DESCRIPTION OF REFERENCE NUMERALS

10 Cooler
11 Working fluid
12 Container
13 heat generating body
14 Cooling member
15 Thin metal wire
16 Working fluid supply section
17 Vapor exhaust section
18 Working fluid introduction body
19 Working fluid introduction section
20 Cooling device
21 Condenser
22 Thin metal film

1. A cooler of a boiling method type for cooling a heat generating body, comprising:
a container for storing a working fluid;
a cooling member made of a porous body and disposed in the container so as to face a surface of the heat generating body; and
at least one thin metal wire or thin metal film disposed between the surface of the heat generating body and the cooling member and configured to be heatable.

2. The cooler according to claim 1, wherein the thin metal wire or thin metal film is configured to be heatable by a passage of electric current.

3. The cooler according to claim 1, wherein a plurality of thin metal wires or thin metal films are provided.

4. The cooler according to claim 1, wherein the porous body comprises a working fluid supply section that supplies the working fluid to the surface of the heat generating body by capillary action, and a vapor exhaust section that exhausts vapor generated on the surface of the heat generating body to the working fluid side.

5. The cooler according to claim 4, wherein the porous body has a honeycomb structure.

6. The cooler according to claim 1, further comprising a working fluid introduction body that is laminated on the working fluid side of the porous body and introduces the working fluid into the porous body.

7. A cooling device comprising:
the cooler according to claim 1; and
a condenser that is connected to the container of the cooler and liquefies evaporated working fluid.
